(19) United States
(12) Patent Application Publication
(10) Pub. No.: US 2006/0180888 A1
(43) Pub. Date: Aug. 17, 2006

(54) Optical sensor package and method of manufacture

(75) Inventors: Teck Tiong Tan, Singapore (SG); Hwee Seng Jimmy Chew, Singapore (SG)

Correspondence Address: CONLEY ROSE, P.C., P. O. BOX 3267, HOUSTON, TX, 77253-3267, US

(73) Assignee: Advanpack Solutions Pte Ltd, Singapore (SG)

(21) Appl. No.: 11/057,646

(22) Filed: Feb. 14, 2005

(51) Int. Cl. H01L 31/0203

(52) U.S. Cl. 257/433

(57) ABSTRACT

A semiconductor package for optical sensing and method of manufacture thereof is disclosed. The semiconductor package comprises a substrate for transmitting radiation and an integrated circuit chip for sensing the radiation. A plurality of connectors for electrical transmission is disposed on the substrate and a plurality of pillars for facilitating electrical communication between the plurality of connectors and the integrated circuit chip is disposed between at least one of the plurality of connectors and the integrated circuit chip.

### FIELD OF INVENTION

The invention relates generally to optical sensors. In particular, the invention relates to semiconductor packages for optical sensing.

### BACKGROUND

Modern image capturing equipment such as digital cameras and imaging-enabled mobile phones are fast becoming indispensable tools for satisfying user needs for communicating through digital images and videos. Many of the image capturing equipment are based on Complementary Metal Oxide Semiconductor (CMOS) or Charge Coupled Device (CCD) technology for optical sensing and capturing images. The images are sensed and captured through image-sensing semiconductor chips such as CMOS and CCD integrated circuit (IC) chips, which are typically packaged into optical sensor packages.

Increasing demands for high manufacturability and quality of the optical sensor packages mean that there are needs for flexibility and reliable methods for packaging the image-sensing chips. Improving conventional methods of packaging the image-sensing chips is therefore desirable in order to achieve optical sensor packages with better operating performances and greater manufacturability.

A conventional method for forming optical sensor packages typically requires an image-sensing chip to be wire bonded to a ceramic substrate. The image-sensing chip is then usually hermetically sealed and covered by a glass filter to protect the image-sensing chip from moisture contamination and provide mechanical protection thereto. The requirements of the ceramic substrate and the glass filter for forming the optical sensor packages increases the dimensions thereof and are undesirable for increasing the compactability of the optical sensor packages. There is also a higher possibility of moisture contamination of the image-sensing chip when the glass filter is defective, thereby resulting in a loss of manufacturing yield and reducing reliability of the optical sensor packages.

Additionally, the conventional method for forming optical sensor packages requires sophisticated controlling means for ensuring each image-sensing chip is thoroughly hermetically sealed. This inevitably causes reduction in manufacturability of the optical sensor packages.

Another conventional method for forming optical sensor packages uses an index matching underfill, which is provided between the image-sensing chip and the glass filter for improving light transmissitivity to the image-sensing chip. Sealing of the image-sensing chip is not required. However, this method requires solder bumps for forming metallurgical bonds between the image-sensing chip and the substrate and is not suitable for other image-sensing chips requiring wire bonding interconnection, especially wire bonding interconnection with fine pitch. This method inherently limits the flexibility of manufacturing optical sensor packages.

Additionally, this method uses an interposer or flexible printed circuit having a center opening in which high accuracy is required in defining the center opening. This undesirably increases the complexity of the method. The use of solder bumps reduces accuracy in positioning the image-sensing chip relative to the glass filter, thereby resulting in a less controllable method for forming the optical sensor packages.

There is therefore a need for an optical sensor package having greater flexibility and controllability in manufacturing thereof.

### SUMMARY

Embodiments of the invention disclosed herein provide improved controllability relating to manufacturing of optical sensor packages. Additionally, the embodiments have greater flexibility in manufacturing the optical sensor packages.

Therefore, in accordance with one aspect of the invention, a semiconductor package for optical sensing is disclosed. The semiconductor package comprises a substrate for transmitting radiation and an integrated circuit chip for sensing the radiation. A plurality of connectors for electrical transmission is disposed on the substrate and a plurality of pillars for facilitating electrical communication between the plurality of connectors and the integrated circuit chip, wherein each of the plurality of pillars is disposed between at least one of the plurality of connectors and the integrated circuit chip.

In accordance with another aspect of the invention, a method for forming a semiconductor package for optical sensing is disclosed. The method comprising the steps of providing a substrate for receiving radiation; disposing a plurality of connectors on the substrate for electrical transmission; providing an integrated circuit chip for sensing the radiation; and connecting the integrated circuit chip to the plurality of connectors on the substrate with a plurality of pillars, wherein each of the plurality of pillars is disposed between at least one of the plurality of connectors and the integrated circuit chip.

### BRIEF DESCRIPTION OF THE DRAWINGS

Embodiments of the invention are described hereinafter with reference to the drawings, in which:

FIG. 1 is a top view of a substrate of a semiconductor package;

FIG. 2 is a top view of a plurality of connectors disposed on the substrate of FIG. 1;

FIG. 3 is a top view of a dielectric material disposed on the plurality of connectors and the substrate;

FIG. 4 is a cross-sectional view of the semiconductor package having an underfill material being dispensed thereon; and

FIG. 5 is a cross-sectional view of the semiconductor package having an integrated circuit chip bonded thereto.

### DETAILED DESCRIPTION

With reference to the drawings, a semiconductor package according to embodiments of the invention having improved controllability and greater manufacturability relating to manufacturing thereof is disclosed.

Various conventional methods for improving quality and manufacturability of optical sensor packages are disclosed herein. The conventional methods face difficulties with the manufacturing yield of packaging image-sensing chips due to a need for the image-sensing chips to be hermetically sealed. Other conventional methods have limitations in the flexibility of manufacturing optical sensor packages.

For purposes of brevity and clarity, the description of the invention is limited hereinafter to applications related to packaging of CMOS and CCD image-sensing chips. This however does not preclude embodiments of the invention from other applications, such as heat sensing chips or other chips for sensing electromagnetic radiation, which require similar packaging methods as the method for packaging the CMOS and CCD image-sensing chips. The functional and operational principles on which the embodiments of the invention are based remain the same throughout the various embodiments.

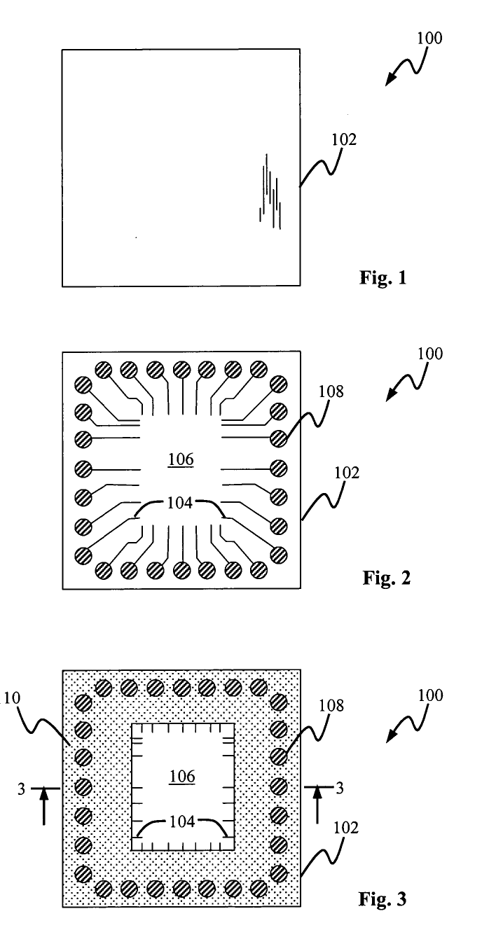

Embodiments of the invention are described in greater detail hereinafter for a semiconductor package 100 for optical sensing and method of manufacture thereof. In the detailed description and illustrations provided in FIGS. 1 to 5 of the drawings, like elements are identified with like reference numerals.

With reference to FIG. 1, a top view of a pre-processed substrate 102 of the semiconductor package 100 for receiving radiation according to a first embodiment of the invention is shown. Examples of radiation receivable by the substrate 102 are visible light emanating from a light source and reflected light from an object. The substrate 102 is light-transmissible and preferably transparent such that visible light is transmitted therethrough with minimal transmission loss.

Additionally, the substrate 102 is preferably capable of filtering infrared (IR) radiation for reducing thermal energy transmitting therethrough. A suitable material for the substrate 102 is IR filtering glass. Alternatively, the substrate 102 is made of glass coated with a layer of IR filtering material. The substrate 102 is preferably but not limited to having a square configuration.

FIG. 2 shows a plurality of connectors 104 for electrical transmission being disposed and distributed according to a first predetermined layout on the substrate 102. The plurality of connectors 104 is formed as conducting tracks for conducting electrical signals and is preferably made of conductive material such as chromium (Cr) and copper (Cu). The conductive material is preferably sputtered onto the substrate 102 for forming the conductive tracks.

The plurality of connectors 104 is preferably arranged around a central portion 106 of the substrate 102. Each end of the plurality of connectors 104 substantially distal to the central portion 106 and proximal to the periphery of the substrate 102 is preferably formed into a pad 108. The pad 108 is preferably formed in conjunction with the plurality of connectors 104 and is preferably but not limited to a circular configuration and electroplated with at least an additional layer of the conductive material, such as Cu with or without surface finishes, for better metallurgical bonding.

A layer of dielectric material 110, such as a coverlay, being formed on the substrate 102 is shown in FIG. 3. The layer of dielectric material 110 is preferably laminated on the substrate 102 and has preformed openings for exposing the central portion 106 of the substrate 102, a portion of the plurality of connectors 104 proximal to the central portion 106 and the pad 108. Alternatively, the layer of dielectric material 110 is spin-coated on the substrate 102 before processes such as photolithography and etching form the perform openings. The layer of dielectric material 110 is preferably opaque and thereby defines areas of the substrate 102 for which visible light is transmittable therethrough. An example of the dielectric material 110 is polyimide (PI) laminated with a layer of Cu.

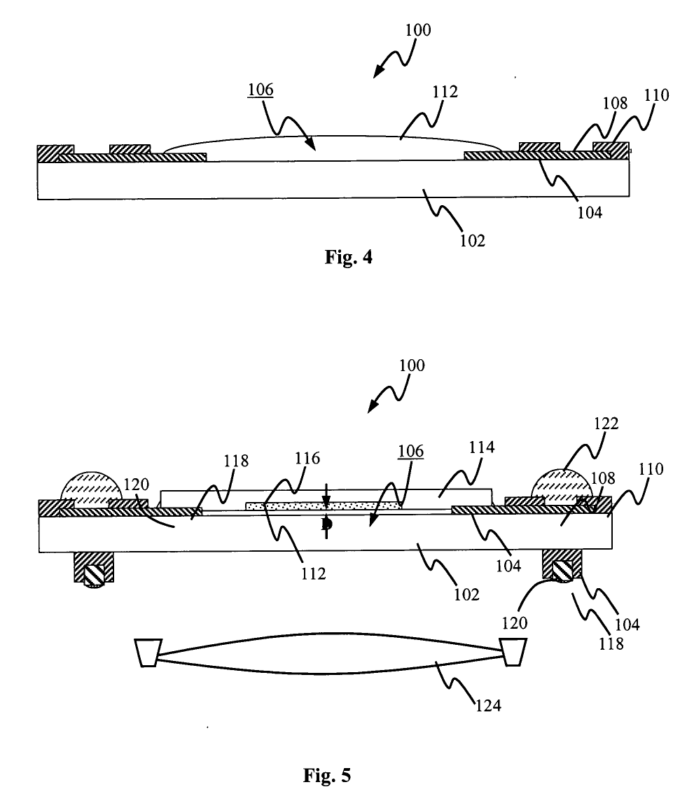

With reference to FIG. 4, a cross-sectional view of the semiconductor package 100 is shown. FIG. 4 is the cross-sectional view of the semiconductor package 100 taken along line 3-3 of FIG. 3. An underfill material 112 is provided on the substrate 102 preferably by a process such as dispensing or printing. The underfill material 112 covers the central portion 106 of the substrate 102 and the portion of the plurality of connectors 104 proximal thereto. The underfill material 112 reduces stress due to thermal expansion miss-match between the plurality of connectors 104 and any metallization being bonded thereto by redistributing the stress induced on the plurality of connectors 104. An example of the underfill material 112 is no-flow underfill (NFU).

As shown in FIG. 5, an integrated circuit chip 114, such as CMOS and CCD image-sensing chips, having a light sensitive area 116 for sensing visible light is bonded to the plurality of connectors 104. The underfill material 112 is transmissible to visible light and prevents moisture contamination of the light sensitive area 116 of the integrated circuit chip 114. The integrated circuit chip 114 has bondpads (not shown) preferably formed at the periphery thereof for connecting the integrated circuit chip 114 to the plurality of connectors 104. Each of the bondpads is preferably plated with a layer of metallization using a similar plating process for forming the additional layer of conductive material on the pad 108 for improving metallurgical bonding. Each of the bondpads is connected to a corresponding connector 104 via a pillar 118. The pillar 118 facilitates electrical communication between the plurality of connectors 104 and the integrated circuit chip 114. The connection of the integrated circuit chip 114 to the plurality of connectors 104 advantageously allows the semiconductor package 100 to achieve compactness.

The pillar 118 preferably extends from the integrated circuit chip 114 and erects substantially upright therefrom. Additionally, the pillar 118 preferably has uniform longitudinal cross-sectional area and is preferably made of conductive materials such as Cu and gold (Au).

A predetermined amount of solder 120 is preferably deposited on one end of the pillar 118 for facilitating bonding of the pillar 118 to the corresponding conductor 104. The solder 120 preferably comprises material such as 63% lead (Pb)/37% Tin (Sn) eutectic composition alloy and pure Sn, as known to a person skilled in the art. The solder 120 is subsequently reflowed for bonding of the pillar 118 to the corresponding conductor 104. The reflowing process is controllable by the amount of solder 120 deposited on the pillar 118. The pillar 118 is preferably not reflowable during the reflowing of the solder 120.

The displacement D between the light sensitive area 116 of the integrated circuit chip 114 and the substrate 102 is an important parameter affecting image quality. It is therefore desirable to achieve high precision for establishing the displacement D. The use of pillars 118 for connecting the integrated circuit chip 114 to the plurality of connectors 104 allows more precision and consistency in establishing the displacement D between the integrated circuit chip 114 and the substrate 102. This advantageously reduces the possibility of focusing error due to imprecision and inconsistency of establishing the displacement D.

Additionally, the semiconductor package 100 of FIG. 5 is suitable for packaging image-sensing chips configured for wire bonding interconnection. The use of the pillar 118 reduces the need for re-routing the image-sensing chips with bondpad pitch of approximately 150 micrometers or less. This also reduces the possibility of bridging of metallurgical bonds for interconnecting the image-sensing chip and the substrate 102.

In a second embodiment of the invention, additional pads (not shown) are formed on the substrate 102 together with the plurality of connectors 104. Corresponding pillars 118 are bonded to the additional pads for improving precision of the displacement D between the integrated circuit chip 114 and the substrate 102 and the positioning of the integrated circuit chip 114 relative to the substrate 102.

The additional pads are alternatively used as fiducial points for advantageously allowing more accurate placement of camera lenses 124 with respect to the substrate 102. The pillars 118 can also be formed on the opposite side of the substrate 102 as alternative alignment structures for the placement of the camera lenses 124. Layers of connector 104 and solder 120 are preferably disposed between the pillars 118 and the opposite side of the substrate 102, as shown in FIG. 5. The fiducial points and alignment structures therefore enable accurate placement of the camera lenses for obtaining digital images with improved quality and manufacturability.

Solder balls 122 are attached to the pads at the periphery of the substrate 102 for bonding the semiconductor package 100 to an external circuitry (not shown), such a printed circuit board (PCB).

In the various embodiments of the invention, the layout of the plurality of connectors 104 and pads 108 are determined by the requirements of designing the semiconductor package 100.

In the foregoing manner, a semiconductor package for optical sensing is disclosed. Although only a number of embodiments of the invention are disclosed, it becomes apparent to one skilled in the art in view of this disclosure that numerous changes and/or modification can be made without departing from the scope and spirit of the invention. For example, although the semiconductor package is formed with a square or polygonic substrate in the forgoing embodiments, the semiconductor package may be efficiently performed if the substrate is of other polygonal or circular shape for receiving the visible light.

1. A semiconductor package for optical sensing, the semiconductor package comprising:
a substrate for transmitting radiation;
a plurality of connectors for electrical transmission, the plurality of connectors being disposed on the substrate;
an integrated circuit chip for sensing the radiation; and
a plurality of pillars for facilitating electrical communication between the plurality of connectors and the integrated circuit chip,
wherein each of the plurality of pillars is disposed between at least one of the plurality of connectors and the integrated circuit chip.

2. The semiconductor package of claim 1, wherein each of the plurality of pillars is non-reflowable.

3. The semiconductor package of claim 1, wherein a layer of dielectric material is formed on the substrate for exposing at least one portion of the substrate and the plurality of connectors.

4. The semiconductor package of claim 1, wherein an underfill material is provided between the substrate and the integrated circuit chip.

5. The semiconductor package of claim 4, wherein the underfill material is optically transmissive.

6. The semiconductor package of claim 1, wherein each of the plurality of pillars is electrically connected to a bondpad on the integrated circuit chip.

7. The semiconductor package of claim 1, wherein each of the plurality of pillars is electrically connected to the plurality of connectors via a layer of bonding material.

8. The semiconductor package of claim 7, wherein the bonding material is reflowable.

9. The semiconductor package of claim 7, wherein the bonding material is solder.

10. The semiconductor package of claim 1, wherein each of the plurality of pillars has substantially uniform longitudinal cross-sectional area.

11. The semiconductor package of claim 1, wherein the plurality of pillars is made from conductive material.

12. The semiconductor package of claim 11, wherein the conductive material comprises at least one of copper and gold.

13. The semiconductor package of claim 1, wherein the plurality of pillars extends from the integrated circuit chip and is erected substantially upright therefrom.

14. The semiconductor package of claim 1, wherein the substrate is optically transmissive.

15. The semiconductor package of claim 1, wherein the substrate filters infrared radiation.

16. The semiconductor package of claim 1, wherein a layer of infrared filtering material is formed on the substrate for filtering infrared radiation.

17. The semiconductor package of claim 1, wherein solder is couplable to one end of the plurality of connectors.

18. A method for forming a semiconductor package for optical sensing, the method comprising the steps of:
providing a substrate for receiving radiation;
disposing a plurality of connectors on the substrate for electrical transmission;
providing an integrated circuit chip for sensing the radiation; and
connecting the integrated circuit chip to the plurality of connectors on the substrate with a plurality of pillars,
wherein each of the plurality of pillars is disposed between at least one of the plurality of connectors and the integrated circuit chip.

19. The method of claim 18, further comprising the step of:
forming a layer of dielectric material on the substrate for exposing at least one portion of the substrate and the plurality of connectors.

20. The method of claim 18, further comprising the step of:
providing an underfill material between the substrate and the integrated circuit chip.

21. The method of claim 18, further comprising the step of:
depositing and reflowing solder on one end of the plurality of pillars for facilitating connection thereof to the plurality of connectors on the substrate.

22. The method of claim 21, further comprising the step of:
coupling the solder formed on one end of the plurality of pillars to at least one of the plurality of connectors
